(19) United States
(12) Patent Application Publication
(10) Pub. No.: US 2023/0158751 A1
(43) Pub. Date: May 25, 2023

(54) SYSTEMS AND METHODS OF DISPLACEMENT CONTROL IN ADDITIVE MANUFACTURING OF ELECTRONIC COMPONENTS

(71) Applicant: ABB Schweiz AG, Baden (CH)

(72) Inventors: Daniel Pierce Armstrong, Cary, NC (US); Matthew Hetrich, Cary, NC (US)

(21) Appl. No.: 17/534,747

(22) Filed: Nov. 24, 2021

(51) Int. Cl. B29C 64/393; B29C 64/209; B33Y 10/00; B33Y 30/00; B33Y 50/02

(52) U.S. Cl. CPC B29C 64/393; B29C 64/209; B33Y 10/00; B33Y 30/00; B33Y 50/02

(57) ABSTRACT

A system of additive manufacturing of a high-voltage electronic component is provided. The system includes a dispenser and a height control assembly. The dispenser has a tip configured to deposit an additive material onto a surface of a substrate. The height control assembly is coupled to the dispenser and configured to detect a distance change of the tip of the dispenser from the surface of the substrate, wherein the height control assembly is further configured to adjust the dispenser based on the detected distance change.

### BACKGROUND

The field of the disclosure relates to manufacturing of electronic components, and more particularly, to additive manufacturing of electronic components.

Different techniques are known to manufacture electronic components such as resistors or voltage dividers by applying a non-insulating, electrically resistive film or foil material onto an insulating substrate. Typical methods are sputtering (thin film) or screen and stencil printing (thick film).

Known systems and methods of manufacturing electronic components are disadvantaged in some aspects and improvements are desired.

### BRIEF DESCRIPTION

In one aspect, a system of additive manufacturing of a high-voltage electronic component is provided. The system includes a dispenser and a height control assembly. The dispenser has a tip configured to deposit an additive material onto a surface of a substrate. The height control assembly is coupled to the dispenser and configured to detect a distance change of the tip of the dispenser from the surface of the substrate, wherein the height control assembly is further configured to adjust the dispenser based on the detected distance change.

In another aspect, a method of additive manufacturing of a high-voltage electronic component is provided. The method includes detecting, via a height control assembly, a distance change of a tip of a dispenser from a surface of a substrate. The method also includes adjusting, via the height control assembly, the dispenser based on the detected distance change and depositing, via the dispenser, an additive material onto the substrate from the tip of the dispenser.

### DRAWINGS

Non-limiting and non-exhaustive embodiments are described with reference to the following Figures, wherein like reference numerals refer to like parts throughout the various drawings unless otherwise specified.

FIG. 1A is a schematic diagram of an exemplary system of additive manufacturing.

FIG. 1B is a schematic diagram of an exemplary embodiment of the system of additive manufacturing shown in FIG. 1A.

FIG. 2 shows an exemplary embodiment of a height control assembly of the system shown in FIG. 1B.

FIG. 3 shows another exemplary embodiment of a height control assembly of the system shown in FIG. 1B.

FIG. 4 is a flow chart of an exemplary method of additive manufacturing.

FIG. 5 shows exemplary voltage dividers manufactured using systems and methods shown in FIGS. 1A-4.

### DETAILED DESCRIPTION

The disclosure includes systems and methods of additive manufacturing of electronic components such as resistors or voltage dividers. Method aspects will be in part apparent and in part explicitly discussed in the following description.

In manufacturing electronic components such as resistors or voltage dividers, the process includes depositing a film onto a substrate, baking the deposition with the substrate in a high temperature furnace such as 850° C., and trimming the resistive path to fine-tune the electronic component. During deposition, a non-insulating, electrically resistive film or foil material, such as metal film or metal foil, e.g., nickel chromium, cermet film, e.g., tantalum nitride, ruthenium dioxide, bismuth ruthenate, carbon film, or a film of composite material based on a mixture of glass and cermet is deposited onto an insulating or dielectric substrate. The insulating substrate may be ceramic, silicon, glass or other synthetic material. In addition, highly conductive structures with considerable lower resistivity than the film material of the resistors are deposited on the substrate as well. The highly conductive structures are intended to be used as contacting terminals, and they are placed on the substrate in such a way that the resistive film material of the resistors overlaps partly with them.

Film material may be applied to the substrate by known methods such as sputtering or screen printing. Sputtering is not suitable for manufacturing resistors having a high resistance value (e.g., 20 M ohm or greater), voltage dividers having a high voltage ratio, or components in high voltage sensors. Screen printing therefore is typically used. Screen printing allows for reasonably high throughput on complex circuit shapes such as those in non-inductive high voltage resistors and other integrated circuits. Screen printing process, however, is inflexible. Screen printing requires a screen or mask to be generated. For low volume parts and circuit designs, it is prohibitively costly to operate a manufacturing line for screen printing for small orders and custom designs. Current suppliers of resistors for high voltage and high power devices have long lead times, such as 4-8 weeks for standard designs and longer for custom orders. Some custom and complex resistors having features such as voltage cushions, integrated voltage dividers, or non-typical resistance values have even longer lead times.

In contrast, an additive manufacturing method offers a high degree of design flexibility whiles still providing relatively high throughput. With additive methods, increased complexity does not require an increase in production cost. Rather than designing screens, the systems and methods disclosed herein provide a simplified, continuous fluid dispensing printer for resistive, conductive and dielectric thin films. Systems and methods described herein provide a low cost printer with multiple movement stages, motors and control system that drastically reduces lead time to a time frame for example less than three days, allows for rapid prototyping of new designs, increases automation, and reduces the overall part count in printing integrated circuits.

In traditional additive manufacturing, a material is dispensed on a surface with defects and/or irregularities that do not exceed an acceptable tolerance. Additive manufacturing typically uses a reusable print surface that may be machined precisely. However, this level of precision becomes less practical when using additive manufacturing on a substrate embedded in the resultant print or electronic component, where the substrate is not reusable. The additional cost to precisely machine each substrate for each electronic component may become prohibitive. In volume manufacturing, tolerances of defects or unevenness of surface of the substrate are increased to lower cost. Further, ceramic substrates used as printing substrates for high voltage resistors and integrated voltage dividers may have significant, unique surface defects that needed be addressed for a high resistive path. Improvements are needed to meet the longstanding and unfulfilled needs in the art.

Systems and methods disclosed herein provide height control of the dispenser and real-time adjustment of height of the dispensing in an additive manufacturing process such that the distance between the tip of the dispenser and the surface of the substrate remains relatively constant. The ink of the additive material has a relatively high viscosity, e.g., greater than 1000 centipoise. As the dispenser or the dispenser travels along the surface of the substrate at a certain speed, the height of the dispenser affects the consistency and amount of ink deposited on the surface of the substrate and therefore the characteristics of the electronic component. The height of the dispenser relative to the surface of the substrate therefore should be precisely controlled to ensure the precision of the printed electronic components. Further, due to the high viscosity of the additive material, the diameter or size of the tip is relatively small, e.g., approximately 100-1000 μm (17-32 gauge) to better control the deposition of the additive material. Pressure applied onto the additive material therefore is relatively large, e.g., 100-125 pound-force per square inch (psi) (689-862 Kilopascal (kPa)). The ink should be dispensed continuously and adjustment of height of the dispenser should be instantaneously or real time, rather than pausing, adjusting, and restarting the dispenser during the manufacturing process. The simple design provided by the systems and methods described herein allows implement in a production environment, not just a laboratory setting, at relatively low cost and high throughput. Additionally, the electrical contact installation and coating process is also automated for high volume production.

Compared to screen-printing, one more advantage of additive manufacturing is that deposition patterns in additive manufacturing are not limited by the screen. In screen-printing, because a screen is required, screen-printing cannot print a pattern having a complete loop that encompasses a circumference of a three-dimensional (3D) substrate such as a cylindrical substrate, limiting designs of electronic components.

Compared to conventional manufacturing of an electrical component, systems and methods described herein are advantageous in manufacturing high voltage electrical components, such as high voltage dividers. In conventional manufacturing of a voltage divider, resistors of the divider and their connections are separately designed and manufactured. Systems and methods described herein provide design flexibility, save space for electrical components, and provide uniform form factors for electrical components. For example, resistors and their connections are included one deposition design on one substrate.

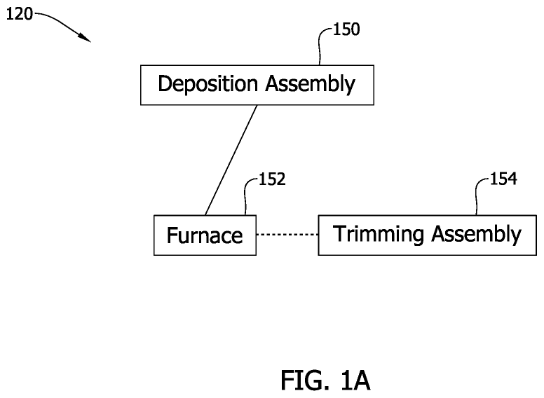

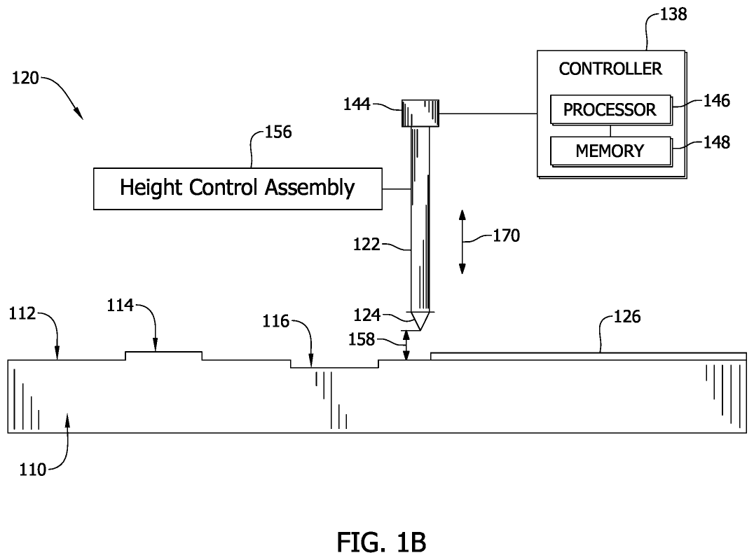

FIGS. 1A and 1B are a schematic diagram of an exemplary system 120 of additive manufacturing of a high-voltage electronic component (FIG. 1A) and an exemplary embodiment of system 120 (FIG. 1B). The electronic component may be a resistor or a voltage divider, which may be used in a voltage sensor. The voltage range of the electronic component may be 3.6 kV or above. Alternatively, the resistance ratio of the voltage divider is greater than 1000:1, or even greater than 10,000:1. In the exemplary embodiment, the system 120 includes a deposition assembly 150 configured to deposit an additive material 126 onto a substrate 110 (FIG. 1B), and a furnace 152 used to bake the printed components. System 120 may include a trimming assembly 154. The systems and methods described herein, however, do not require a trimming assembly 154.

Additive manufacturing is applied to a substrate 110. For example, substrate 110 is configured to form a voltage divider for use in a high voltage sensor. Substrate 110 is generally a dielectric substrate, e.g. a ceramic material or plastic, that does not conduct electricity. Substrate 110 includes a surface 112 that is configured to receive an additive material, such as a conductive material or a resistive paste that is applied using additive manufacturing. Surface 112 include imperfections where surface 112 is not entirely flat. That is, surface 112 may include raised portions 114 and/or recessed portions 116. In some embodiments, surface 112 is non-planar. For example, substrate 110 is generally cylindrical in shape.

In the exemplary embodiment, deposition assembly 150 of system 120 includes a dispenser 122, an actuator 144, and a height control assembly 156. A dispenser may also be referred to as a dispensing needle. Dispenser 122 may be a pneumatic dispenser, a syringe pump dispenser, or other dispensing devises configured to dispense a material having a high viscosity, e.g., greater than 1000 centipoise. The dispenser includes a dispensing tip 124. The size of tip 124 may be in the range of approximately 100-1000 μm. Tip 124 of dispenser 122 is moved along surface 112 of substrate 110 to apply an additive material 126 to surface 112.

In the exemplary embodiment, height control assembly 156 is configured to monitor or detect changes in a distance 158 between tip 124 of dispenser 122 from surface 112 of substrate 110. A distance between a point and a surface is the distance between the point and the projection of the point to the surface. system 120 further includes an actuator 144. Actuator 144 is a linear actuator, where actuator 144 moves in a direction perpendicular to surface 112 of substrate. That is, actuator 144 moves along a height direction 170 of dispenser 122.

System 120 may further include a controller 138 in communication with actuator 144 and height control assembly 156. In some embodiments, controller 138 includes a processor-based microcontroller including a processor 146 and a memory device 148 wherein executable instructions, commands, and control algorithms, as well as other data and information needed to satisfactorily operate system 120, are stored. Memory 148 includes instructions that when executed by processor 146 enable controller 138 to process the distance change detected by height control assembly 156 and in response to the distance change, to raise or lower tip 124 of dispenser 122 relative to surface 112 of substrate 110. In some embodiments, memory device 148 may be, for example, a random access memory (RAM), and other forms of memory used in conjunction with RAM memory, including but not limited to flash memory (FLASH), programmable read only memory (PROM), and electronically erasable programmable read only memory (EEPROM).

As used herein, the term “processor-based” microcontroller shall refer not only to controller devices including a processor or microprocessor as shown, but also to other equivalent elements such as microcomputers, programmable logic controllers, reduced instruction set circuits (RISC), application specific integrated circuits and other programmable circuits, logic circuits, equivalents thereof, and any other circuit or processor capable of executing the functions described below. The processor-based devices listed above are exemplary only, and are thus not intended to limit in any way the definition and/or meaning of the term “processor-based.”

In operation, height control assembly 156 detects changes in distance 158 between tip 124 of dispenser 122 and surface 112 of substrate 110. As system 120 applies additive material 126 to surface 112, increases in the distance 158 are indicative of the tip having reached a recessed portion 16 where the dispenser is farther from surface 112. In response, controller 38 lowers dispenser tip 24 to uniformly apply additive material 126 to recessed portion 116. In contrast, decreases in the distance 158 are indicative of dispenser tip 124 passing over a raised portion 114 of surface 112. In response, controller 138 raises dispenser tip 124 to uniformly apply additive material 126 to raised portion 114.

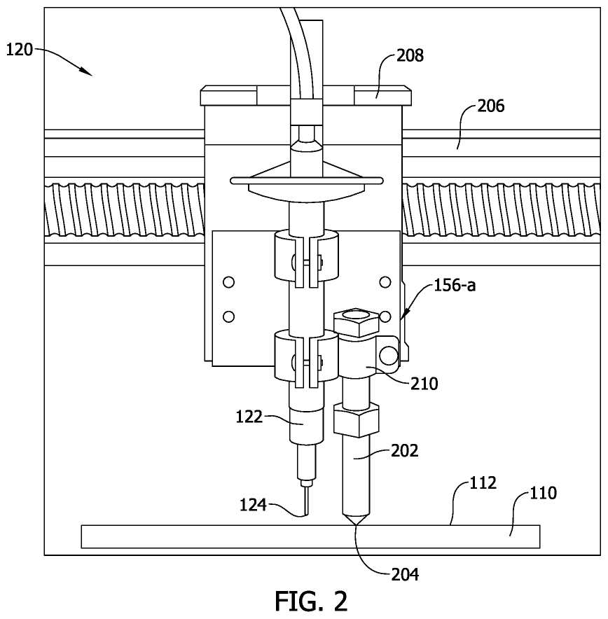

FIG. 2 shows an exemplary embodiment of height control assembly 156-a. In the exemplary embodiment, height control assembly 156 includes a pole 202 offset from dispenser 122 and a ballpoint contactor 204 at an end of pole 202. Ballpoint contactor 202 is fabricated from a rigid material such that ballpoint contactor 204 does not wear off or leave particles on substrate 110. The material of ballpoint contactor 204 may include polytetrafluoroethylene, hardened steel, or tungsten carbide. Pole 202 is generally parallel to dispenser 122. Pole 202 extends farther out from track 206 than dispenser such that ballpoint contactor 204 becomes in contact with surface 112 while dispenser 122 is not in contact with surface 112 when surface 112 is even at locations directly below ballpoint contactor 204 and tip 124 of dispenser 122. A location on a surface directly below a point is the projection of the point onto the surface. Substrate 110 acts as a cam and ballpoint contactor 204 acts as a follower of the cam to follow surface 112 of substrate 110 such that ballpoint contactor 204 moves up or down as surface 112 raises or recesses. Height control assembly 156 is positioned proximate to dispenser 122. For example, the distance or offset between ballpoint contactor 204 and tip 124 of dispenser 122 is less than 1 mm. As a result, the distance change detected by height control assembly 156 is approximately the same as the distance change in distance 158. Both height control assembly 156 and dispenser 122 are positioned on and attached to stage 208 such that height control assembly 156 moves together with dispenser 122. Height control assembly 156 is coupled with stage 208 through a buckle 210. Other coupling mechanisms may be used to couple height control assembly 156 with stage 208 and therefore with dispenser 122. Stage 208 may be mounted on a linear mounting track 206. Track 206 may be spring loaded. Because dispenser 122 moves together with ballpoint contactor 204, ballpoint contactor 204 maintains a constant distance 158 between tip 124 of dispenser 122 and surface 112 of the substrate 110. When ballpoint contactor 204 becomes in contact with raised portion 114, dispenser 122 is raised. When ballpoint contactor 204 becomes in contact with recesses portion 116, dispenser 122 is lowered.

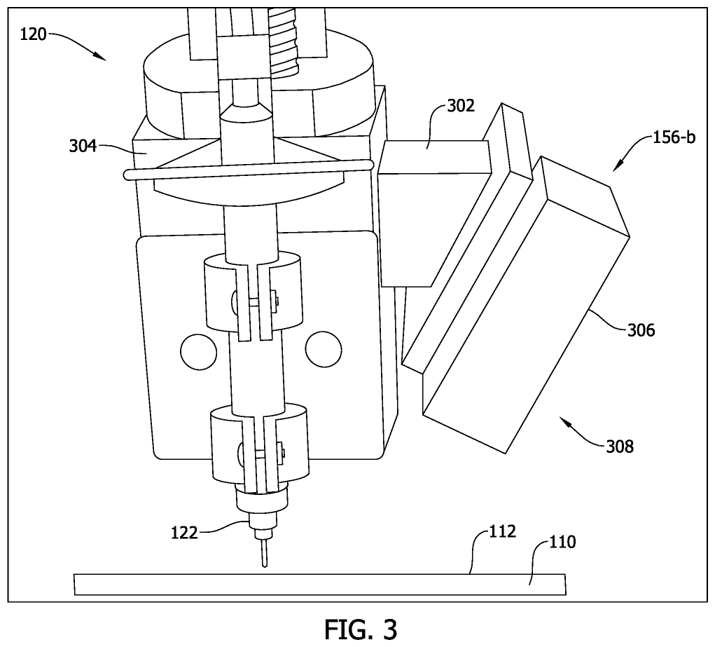

FIG. 3 shows another exemplary embodiment of height control assembly 156-b. In the exemplary embodiment, both height control assembly 156 and dispenser 122 are attached to stage 208. Height control assembly 156 is attached to stage 208 at an arm 302 extending from a body 304 of stage 208. Body 304 includes holders sized to receive dispenser 122 therein. As a result, height control assembly 156 moves together with dispenser 122. Height control assembly 156 includes a sensor 306 that measures distance between sensor 306 and substrate 110. Sensor 306 includes an emitter 308 configured to emit a signal. Sensor is configured to detect a return signal reflected by surface 112 of substrate 110. In the depicted embodiment, sensor 306 is a time of flight (TOF) sensor or camera, which is configured to emit light toward substrate 110, receive a return signal or light reflected by surface 112 of substrate, and measure the distance between the camera and the substrate based on the time of flight between the emitted light and the reflected light. The light may be laser. Sensor 306 may be an 8 μm laser TOF sensor, which has an accuracy of 8 μm or higher or the error of the measurement is 8 μm or less. The light is aimed at a location on surface 112 of substrate 110 directly below tip 124 of dispenser 122. In some embodiments, sensor 306 is a capacitive sensor configured to measure distance from sensor 306 to substrate 110. Height control assembly 156 may include controller 138 configured to process the signals and provide distance measurements. Alternatively, signals are transmitted to and being processed by controller 138 located separately from height control assembly 156. Controller 138 controls actuator 144 (see FIG. 1B) to adjust the height of dispenser based on the detected distance change. Actuator 144 may be a ball screw stepper motor or a piezoelectric actuator.

In operation, the distance changes detected by height control assembly 156 are indicative the distance changes between tip 124 of dispenser 122 and surface 112 of substrate. Controller 138 is configured to adjust the height of dispenser 122 based on the distance changes by instructing actuator to raise or lower stage 208 based on the distance changes. An increase in the distance measured by height control assembly indicates that tip 124 has reached recessed portion 116 and actuator 144 lowers stage 208. On the other hand, a decrease in the distance indicates that tip 124 has reached raised portion and actuator 144 raises stage 208.

Compared to height control assembly 156-a shown in FIG. 2, height control assembly 156-b is contactless and does not become in contact with surface 112 of substrate 110, without concern of material of height control assembly 156-a being worn off or left in substrate 110. Further, the distance changes detected by height control assembly 156-b are more accurate than distance changes detected by height control assembly 156-a because height control assembly 156 measures the location directly below tip 124 of dispenser, instead of the location directly below ballpoint contactor 204.

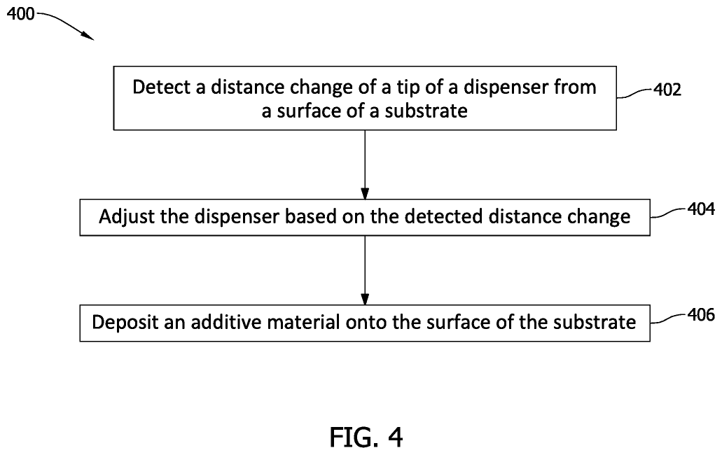

FIG. 4 is a flow chart showing an exemplary method 400 of additive manufacture. Method 400 includes detecting 402 a distance change of a tip of a dispenser from a surface of a substrate. Method 400 also includes adjusting 404 the dispenser based on the detected distance change. Further, method 400 includes depositing 406 an additive material onto the surface of the substrate. In conventional screen printing or additive manufacturing of electronic components, trimming is needed to fine tune the electronic components. Trimming is expensive and time consuming. Because the height of dispenser 122 is precisely controlled and adjusted based on surface 112 of substrate 110, the deposited additive material corresponds to the designed pattern for the electronic component, and trimming of the electronic component is not needed to fine tune the electronic component, thereby saving cost in machinery and labor.

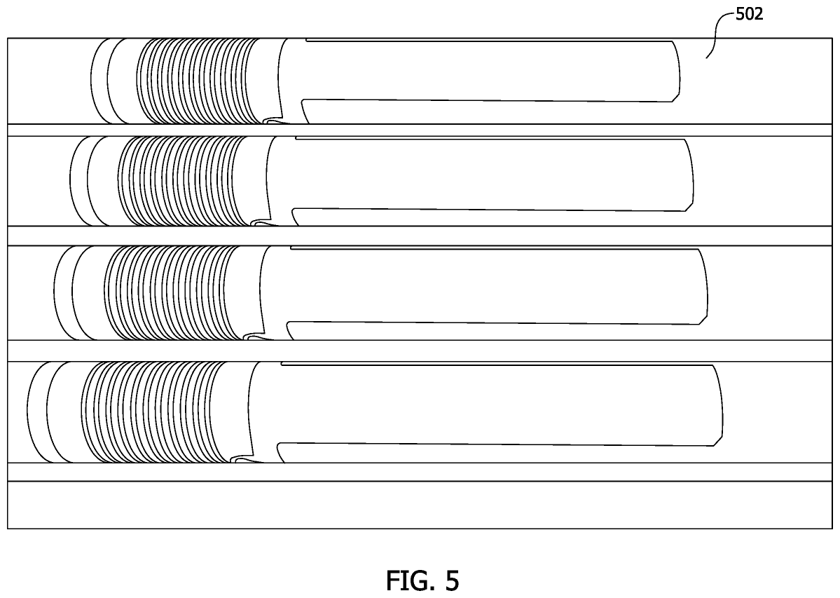

FIG. 5 shows voltage dividers 502 manufactured using systems and methods described herein. Printed resistive voltage dividers 502 have a high aspect ratio primary resistive path, and a low aspect ratio secondary path. Line widths (i.e. print resolution) of 300-800 microns have been generated, though larger line widths are clearly possible. The printer has generated prints of resistors with resistance values as high as 50 MOhm, and higher resistances up to at least 5 GOhms are feasible. Printed path lengths may be at 1.6 meters with an aspect ratio of as high as 4000:1. Additionally, overlapping printed paths have been generated to create large printed areas with low aspect ratios.

As used herein, the terms “processor” and “computer,” and related terms, e.g., “processing device,” “computing device,” and “controller” are not limited to just those integrated circuits referred to in the art as a computer, but broadly refers to a microcontroller, a microcomputer, an analog computer, a programmable logic controller (PLC), an application specific integrated circuit (ASIC), and other programmable circuits, and these terms are used interchangeably herein. In the embodiments described herein, “memory” may include, but is not limited to, a computer-readable medium, such as a random-access memory (RAM), a computer-readable non-volatile medium, such as a flash memory. Alternatively, a floppy disk, a compact disc-read only memory (CD-ROM), a magneto-optical disk (MOD), and/or a digital versatile disc (DVD) may also be used. Also, in the embodiments described herein, additional input channels may be, but are not limited to, computer peripherals associated with an operator interface such as a touchscreen, a mouse, and a keyboard. Alternatively, other computer peripherals may also be used that may include, for example, but not be limited to, a scanner. Furthermore, in the example embodiment, additional output channels may include, but not be limited to, an operator interface monitor or heads-up display. Some embodiments involve the use of one or more electronic or computing devices. Such devices typically include a processor, processing device, or controller, such as a general purpose central processing unit (CPU), a graphics processing unit (GPU), a microcontroller, a reduced instruction set computer (RISC) processor, an ASIC, a programmable logic controller (PLC), a field programmable gate array (FPGA), a digital signal processing (DSP) device, and/or any other circuit or processing device capable of executing the functions described herein. The methods described herein may be encoded as executable instructions embodied in a computer readable medium, including, without limitation, a storage device and/or a memory device. Such instructions, when executed by a processing device, cause the processing device to perform at least a portion of the methods described herein. The above examples are not intended to limit in any way the definition and/or meaning of the term processor and processing device.

At least one technical effect of the systems and methods described herein includes (a) additive manufacturing of electronic components; (b) controlling height of a dispenser to maintain consistency in deposition; and (c) real-time adjustment of the height of the dispenser to allow continuous deposition of an additive material.

Exemplary embodiments of systems and methods of additive manufacturing of electronic components are described above in detail. The systems and methods are not limited to the specific embodiments described herein but, rather, components of the systems and/or operations of the methods may be utilized independently and separately from other components and/or operations described herein. Further, the described components and/or operations may also be defined in, or used in combination with, other systems, methods, and/or devices, and are not limited to practice with only the systems described herein.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A system of additive manufacturing of a high-voltage electronic component, the system comprising:
a dispenser having a tip configured to deposit an additive material onto a surface of a substrate; and
a height control assembly coupled to the dispenser and configured to detect a distance change of the tip of the dispenser from the surface of the substrate, wherein the height control assembly is further configured to adjust the dispenser based on the detected distance change.

2. The system of claim 1, wherein the system does not include a trimming assembly.

3. The system of claim 1, wherein the height control assembly includes a ballpoint contactor positioned on the surface of the substrate, wherein the substrate serves as a cam and the ballpoint contactor serves as a follower of the cam.

4. The system of claim 3, wherein the ballpoint contactor includes polytetrafluoroethylene.

5. The system of claim 1, wherein the height control assembly does not contact the surface of the substrate.

6. The system of claim 1, wherein the height control assembly further includes an emitter, the emitter is configured to transmit an emitted signal toward the substrate, and the height control assembly is configured to detect a return signal reflected by the substrate and detect the distance change based on the emitted signal and the return signal.

7. The system of claim 6, wherein the emitter is a laser emitter.

8. The system of claim 6, wherein the emitter is configured to transmit light toward the substrate.

9. The system of claim 8, wherein the emitter is configured to transmit the light toward the surface of the substrate at a location directly below the tip of the dispenser.

10. The system of claim 1, wherein the system includes a linear actuator.

11. A method of additive manufacturing of a high-voltage electronic component, the method comprising:
detecting, via a height control assembly, a distance change of a tip of a dispenser from a surface of a substrate;
adjusting, via the height control assembly, the dispenser based on the detected distance change; and
depositing, via the dispenser, an additive material onto the substrate from the tip of the dispenser.

12. The method claim 11, wherein the method does not include trimming the electronic component.

13. The method of claim 11, wherein the height control assembly includes a ballpoint contactor, the height control assembly coupled to the dispenser, wherein the substrate serves as a cam and the ballpoint contactor serves as a follower of the cam, and the method further comprises placing the height control assembly on the surface of the substrate.

14. The method of claim 13, wherein the ballpoint contactor includes polytetrafluoroethylene.

15. The method of claim 11, wherein the height control assembly does not contact the surface of the substrate.

16. The method of claim 11, wherein detecting further comprises:
energizing an emitter coupled to the dispenser to transmit an emitted signal from the emitter toward the substrate; and
detecting a return signal reflected by the substrate.

17. The method of claim 16, wherein the emitted signal is laser.

18. The method of claim 16, wherein energizing further comprises energizing the emitter to transmit light toward the substrate.

19. The method of claim 18, wherein energizing further comprises energizing the emitter to transmit the light toward the surface of the substrate at a location directly below the tip of the dispenser.

20. The method of claim 11, wherein the dispenser is coupled to a linear actuator.
